(19) United States
(12) Patent Application Publication
(10) Pub. No.: US 2010/0332706 A1
(43) Pub. Date: Dec. 30, 2010

(54) SENSOR TRANSMITTER DEVICE AND METHOD FOR TRANSMITTING THE PAYLOAD DATA OF A SENSOR TO A BUS CONTROL DEVICE

(75) Inventors: Michael Hering, Leonberg (DE); Felix Eberli, Bassersdorf (CH); Leonardo Leone, Rohr (CH); Michael Helme, Esslingen (DE); Roland Preiss, Erding (DE); Detlef Kunz, Renningen (DE)

Correspondence Address: Gerard A. Messina;Kenyon & Kenyon LLP, One Broadway, New York, NY, 10004, US

(73) Assignee: Robert Bosch GmbH, Stuttgart (DE)

(21) Appl. No.: 12/821,842

(22) Filed: Jun. 23, 2010

(30) Foreign Application Priority Data
Jun. 25, 2009 (DE) 10 2009 027 201.1

(51) Int. Cl. G06F 13/42; H03M 13/00; G06F 13/14

(52) U.S. Cl. 710/106; 340/943; 714/758; 710/305; 714/E11.03

(57) ABSTRACT

A sensor transmitter device for transmitting the payload data of a sensor to a bus control device is described, the sensor transmitter device being connectable to a data bus of a vehicle, which is configured for simultaneous transmission of bus data packets between a plurality of sensor transmitter devices and a bus control device. The bus data packets should include at least one signaling field and one payload data field having a plurality of payload data blocks. The sensor transmitter device includes a sensor interface for receiving payload data which represent a physical variable and a memory which is configured for storing position information which identifies at least one payload data block from the payload data field, which is reserved exclusively for the transmission of payload data from the sensor transmitter device to the bus control device. The sensor transmitter device also includes a bus interface which is configured for placing, after receiving predetermined signaling data in the signaling field, at least part of the payload data received via the sensor interface in the payload data block specified by the position information.

### RELATED APPLICATION INFORMATION

The present application claims priority to and the benefit of German patent application no. 10 2009 027 201.1, which was filed in Germany on Jun. 25, 2009, the disclosure of which is incorporated herein by reference.

### FIELD OF THE INVENTION

The present invention relates to a sensor transmitter device, a bus control device, a method according to claim 12, and a method and a computer program product.

### BACKGROUND INFORMATION

Ultrasound-based driver assistance systems (US-FAS), in particular ultrasound-based parking assistance systems (USEPH), have been on the market for over ten years. Current systems usually employ a proprietary point-to-point link to connect the ultrasound sensors (USS) to a central analyzer unit.

Automobile manufacturers require that the proprietary point-to-point link between the sensors and the central analyzer unit be replaced by a “bus approach” to allow the wiring costs in the vehicle to be reduced. Normally the LIN bus (LIN=Local Interconnect Network) may be used as the standardized and cost-optimized bus system in vehicles.

However, the “standard LIN bus approach” lowers the achievable quality (update rate and/or robustness) of the ultrasound-based driver assistance system, since the update rate of the ultrasound measurements is limited due to the large amount of signaling resources required for the LIN bus communication.

The fact that when small amounts of data (1-2 bytes of payload data per sensor and measurement) are to be transmitted, the communication overhead of the LIN bus is very high (4 bytes), i.e., the net data rate is 20% (for 1 byte of payload data) or 33% (for 2 bytes of payload data).

The limited update rate of the ultrasound measurement is especially relevant during the active ultrasound-based driver assistance system operation, i.e., for transmitting measured values.

In the above estimate, the net data rate-lowering tie of the LIN messages to “scheduling tables,” (i.e., to fixed time grids having discrete periodic transmission times) is not taken into account. This has a negative effect on the net data rate in the case of both many short messages and few long LIN messages.

DE 10 2005 054390 A1 discloses a driver assistance system having a control unit and a plurality of sensors which emit and receive sound waves, and are connected to the control unit via a bus system. The bus system is configured in the form of a shift register. The use of such a bus system, which is configured as a shift register, requires, however, again a separate bus for connecting the individual sensors to an analyzer unit, so that a central bus already installed in the vehicle cannot be used for transmitting such sensor data to a central analyzer unit. Such a standalone approach to data transmission should, however, be avoided, as described above.

### SUMMARY OF THE INVENTION

Against this background, the exemplary embodiments and/or exemplary methods of the present invention provides a sensor transmitter device, a method for transmitting the payload data of a sensor to a bus control device, a bus control device, a method for assigning payload data from a bus data packet to different sensor transmitter devices, and a computer program product. Advantageous embodiments of the present invention are derived from the description that follows.

The exemplary embodiments and/or exemplary methods of the present invention provides a sensor transmitter device for transmitting the payload data of a sensor to a bus control device, the sensor transmitter device being connectable to a data bus of a vehicle, which is configured for simultaneous transmission of bus data packets between a plurality of sensor transmitter devices and a bus control device, the bus data packets each including at least one signaling field and one payload data field having a plurality of payload data blocks, and the sensor transmitter device having the following features:
a sensor interface for receiving payload data which represent a physical quantity;
a memory, which is configured for storing position information which identifies at least one payload data block from the payload data field, which is reserved exclusively for the transmission of payload data from the sensor transmitter device to the bus control device;
a bus interface which is configured for placing, after receiving predetermined signaling data in the signaling field, at least part of the payload data received via the sensor interface in the payload data block of the bus data packet specified by the position information, to which the signaling data are assigned.

Furthermore, the exemplary embodiments and/or exemplary methods of the present invention provides a method for transmitting the payload data from a sensor transmitter device to a bus control device, using a data bus, which is configured for simultaneous transmission of bus data packets between a plurality of sensor transmitter devices and a bus control device, the bus data packets each including at least one signaling field and one payload data field having a plurality of payload data blocks, and the method having the following steps:
receiving payload data of a sensor which represent a physical quantity;
reading position information which identifies at least one payload data block from the payload data field, which is reserved exclusively for the transmission of payload data of the sensor transmitter device to the bus control device; and
receiving predetermined signaling data in the signaling field of a bus data packet and placing, in response thereto, at least part of the payload data received via the sensor interface in the at least one payload data block of the bus data packet specified by the position information.

The exemplary embodiments and/or exemplary methods of the present invention also provides a bus control device for assigning payload data from a bus data packet to different sensor transmitter devices, the bus control device being connectable to a data bus of a vehicle, which is configured for simultaneous transmission of bus data packets between a plurality of sensor transmitter devices and a bus control device, the bus data packets each including at least one signaling field and one payload data field having a plurality of payload data blocks, and the bus control device having the following features:
a transmitter unit which is configured for placing predetermined signaling data in the signaling field of a bus data packet and for transmitting the signaling data to the data bus;
a memory, which is configured for storing an assignment formula of an exclusive reservation of payload data blocks of the payload data field for transmitting the payload data of the different sensor transmitter devices to the bus control device;
a receiving interface which is configured to read, in response to the predetermined signaling data in the signaling field emitted by the transmission interface, payload data from the payload data blocks of the payload data field; and
an assignment unit, which is configured for assigning the read payload data to the different sensor transmitter devices according to the assignment formula.

Finally, the exemplary embodiments and/or exemplary methods of the present invention provides a method for assigning payload data from a bus data packet to different sensor transmitter devices, the bus control device being connectable to a data bus of a vehicle, which is configured for simultaneous transmission of bus data packets between a plurality of sensor transmitter devices and the bus control device, the bus data packets including at least one signaling field and one payload data field having a plurality of payload data blocks, and the method having the following steps:
placing predetermined signaling data in the signaling field of a bus data packet and transmitting the predetermined signaling data to the data bus;
retrieving an assignment formula from a memory, the assignment formula representing an exclusive reservation of individual payload data blocks of the payload data field for transmitting the payload data of the corresponding sensor transmitter device to the bus control device;
reading the payload data from the payload data blocks of the payload data field in response to the transmitted predetermined signaling data in the signaling field; and
assigning the read payload data to the different sensor transmitter devices according to the assignment formula.

The sensor transmitter device or bus control device of the present invention may be configured to carry out or implement the steps of the method according to the present invention. An object of the exemplary embodiments and/or exemplary methods of the present invention may also be achieved via these embodiment variants of the present invention in the form of a sensor transmitter device or a bus control device.

A sensor transmitter device or a bus control device may be understood here as an electrical device which processes sensor signals and, as a function thereof, outputs control signals. The sensor transmitter device or bus control device may have an interface which may be embodied as hardware and/or software. In a hardware embodiment, the interfaces may be part of a so-called system ASIC which contains different functions of a control unit. It is, however, also possible that the interfaces are independent, integrated circuits or at least contain discrete components. In a software embodiment, the interfaces may be software modules which are present, for example, on a microcontroller along with other software modules.

Also advantageous is a computer program product having program code, which is stored on a machine-readable medium, such as a semiconductor memory, a hard disk memory, or an optical memory, and is used for carrying out and/or triggering the steps of the method according to the above-described exemplary embodiments when the program is executed in the sensor transmitter device or the bus control device.

The exemplary embodiments and/or exemplary methods of the present invention is based on the recognition that the data format of a data bus already present may be efficiently used for transmitting the payload data of a plurality of sensors to a central analyzer unit or bus control unit for rearranging the data to be transmitted. It is not necessary to use a complete bus data packet for each sensor, but a plurality of sensors or their transmitter units may be connected together to form a “virtual unit.” Payload data originating from a plurality of sensors may thus be integrated into the payload data field of a single bus data packet. In this way, the signaling complexity is reduced, since a larger amount of payload data may now be transmitted with one bus data packet. In order to carry out such data transmission from a plurality of sensors to the analyzer unit or the bus control unit without error, predetermined signaling information or predetermined signaling data from a set of different signaling data should be placed in the signaling field of such a bus data packet indicating to the sensor transmitter devices that a bus data packet of the payload data blocks, which will be analyzed by the bus control device according to a predetermined assignment formula of the payload data blocks in the payload data field, is now being transmitted over the data bus to the corresponding sensor transmitter devices.

The exemplary embodiments and/or exemplary methods of the present invention offers the advantage that a bus system that is often already present in vehicles may be efficiently used for further data transmission between additional sensors and an analyzer unit (or the bus control device). In this way, a correspondingly rapid data transmission is ensured and, furthermore, the costs for a proprietary link of sensors to an analyzer unit may be avoided. Using the approach proposed herein, the vehicle manufacturing costs may be reduced while the data transmission functionality or the data transmission speed is kept unchanged or is improved.

In an advantageous exemplary embodiment of the present invention, the bus interface may be configured so that no payload data received from the sensor interface is placed in at least one payload data block of the payload data field. An exemplary embodiment of this type of the present invention offers the advantage that the payload data field is not occupied by payload data of a single sensor transmitter device, but payload data from different sensor transmitter devices may be bundled in one bus data packet. This results in the above-named advantages due to a reduction in the signaling complexity.

In another exemplary embodiment of the present invention, in which the bus data field also includes a control data field, the bus interface may be configured so that, from those payload data blocks which are not reserved for exclusive payload data transmission from the sensor transmitter device, transmission data from at least one other sensor transmitter device are extracted and control data are ascertained from the extracted transmission data and at least part of the sensor payload data received from the sensor interface, and the bus interface is furthermore configured for placing the ascertained control data in the control data field of the bus data packet. An exemplary embodiment of this type of the present invention offers the advantage that the data format of a data bus may be easily preserved even if the payload data in the payload data blocks originate from different sensor transmitter devices. In this way, other units or sensors connected to the data bus may be advantageously prevented from being interfered with by the data transmission from the sensor transmitter device to the bus control device.

The bus interface may also be configured to divide the payload data received from the sensor interface into a plurality of partial payload data and to transmit the different partial payload data in payload data blocks of different bus data packets to the bus control device. An exemplary embodiment of this type of the present invention offers the advantage that, even for larger amounts of payload data provided to the sensor, efficient data transmission from sensor to bus control device becomes possible. Using such a division, the payload data field of the bus data packet may be filled optimally, taking into account the data transmission from a plurality of sensors to the central unit.

In order to prevent an error from occurring due to the division and transmission of the payload data in different partial payload data, or, if such an error occurs, to make it easy to recognize, the bus interface may be configured to determine error recognition data from several pieces of payload data and to transmit the error recognition data in a payload data block of another bus data packet, assigned to the sensor transmitter device exclusively for data recognition, to the bus control device.

In particular, for the fastest possible transmission of safety-relevant sensor measured values to an analyzer unit, the bus interface may be configured for transmitting partial payload data having a high priority for driving safety of the vehicle to the bus control device earlier than partial payload data having a low priority for the driving safety of the vehicle.

According to another exemplary embodiment of the present invention, the assignment unit may also be configured for obtaining a sequence of payload data for a single sensor transmitter device from consecutive bus data packets, the assignment unit being also configured for recognizing a transmission error of the payload data for the corresponding sensor transmitter device, using the sequence of payload data. An exemplary embodiment of this type of the present invention offers the advantage that even when the payload data of a single sensor transmitter device are split into a plurality of bus data packets, an error in the transmission of all the payload data for the particular sensor transmitter device may be recognized.

In another exemplary embodiment of the present invention, in which the payload data of a sensor transmitter device have a data volume which is to be transmitted as partial payload data in payload data blocks of a plurality of consecutive bus data packets to the bus control device, the bus control device may be configured to activate another unit prior to analyzing second partial payload data after receiving first partial payload data in a payload data block of a first bus data packet; the second partial payload data may be received from the bus control device in a payload data block of a subsequent bus data packet. An exemplary embodiment of this type of the present invention offers the advantage that sensor data related to the driving safety of a vehicle may be transmitted rapidly to an analyzer unit or to the bus control device, so that, for example, an appropriate passenger protection arrangement may be activated in a timely manner. Further payload data of a sensor which do not have such a high priority may then be received in subsequent bus data packets from the bus control device and no longer impair a rapid response to the safety-relevant information.

The present invention is elucidated in greater detail below on the basis of the attached drawings as an example.

### BRIEF DESCRIPTION OF THE DRAWINGS

FIG. 1a, FIG. 1b, and FIG. 1C show a structure of data packets in a conventional data transmission compared to the structure of a data packet on the data bus according to a first exemplary embodiment of the present invention.

FIG. 2 shows a block diagram of a data transmission system using an exemplary embodiment of the sensor transmitter device according to the present invention and an exemplary embodiment of the bus control device according to the present invention.

FIG. 3a and FIG. 3b show detailed depictions of the structure of a data packet when the payload data transmission principle proposed herein is used.

FIG. 4 shows a structure of data packets in a conventional data transmission compared to a structure of a data packet on the data bus according to a second exemplary embodiment of the present invention.

FIG. 5 shows a communication structure matrix in the transmission according to exemplary embodiments of the present invention.

FIG. 6 shows a structure of data packets in a conventional data transmission compared to the structure of a data packet on the data bus according to a third exemplary embodiment of the present invention, the time advantage of a timely transmission of intermediate results of the payload data being recognizable.

FIG. 7a, FIG. 7b, and FIG. 7C show communication structure matrices, i.e., a table illustrating an improvement in the error recognition according to another exemplary embodiment of the present invention.

FIG. 8 shows a flow chart of an exemplary embodiment of the present invention as a method.

FIG. 9 shows a flow chart of another exemplary embodiment of the present invention as a method.

### DETAILED DESCRIPTION

The same or similar elements may be provided with the same or similar reference numerals in the following figures, a repeat description of these elements being dispensed with. Furthermore, the figures of the drawing, their description, and the claims contain a combination of a plurality of features. Those skilled in the art are aware of the fact that these features may be regarded individually or may be combined to form other combinations not explicitly described herein. Furthermore, the exemplary embodiments and/or exemplary methods of the present invention is elucidated in the description that follows using different measures and dimensions; the naming of these measures and dimensions of the exemplary embodiments and/or exemplary methods of the present invention is understood to not be limited to these measures and dimensions.

An object of the exemplary embodiments and/or exemplary methods of the present invention is to enhance the real-time capability of a data bus in a vehicle, for example, of the LIN bus, in such a way that the perceivable quality (update rate and/or robustness), in particular of the ultrasound-based driver assistance systems, does not or does not significantly differ from the data transmission having a quality achievable using a proprietary point-to-point ultrasound sensor link. Other sensors may also be connected to an analyzer unit via the principle presented herein, so that the exemplary embodiments and/or exemplary methods of the present invention is not limited to the connection of ultrasound-based sensors to a central analyzer unit.

This “top level” requirement may be achieved by increasing the net data rate and by a possibility of rapid transmission of intermediate results. At the same time, the communication for the one central analyzer unit (for example, a LIN communication master) should continue to correspond to the LIN communication standard. In this way, it may be ensured that the data bus communication structure (i.e., for example, the LIN data packet structure) and the maximum (gross) data rate (of 20 kBit when using the LIN bus) may be preserved.

The exemplary embodiments described below are elucidated using a LIN bus as a data bus; other bus systems may be used in vehicles as a data bus according to the principle according to the exemplary embodiments and/or exemplary methods of the present invention.

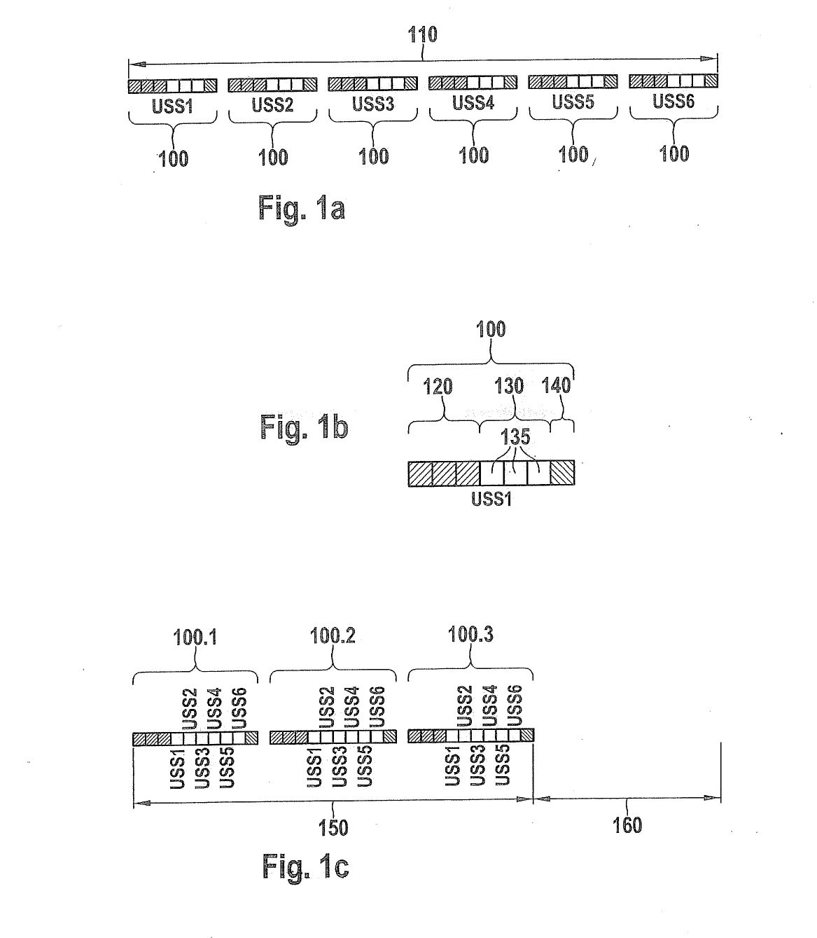

The illustrations of FIGS. 1a, 1b, and 1c show a conventional transmission of payload data of a sensor via a data bus compared with the high transmission rate of payload data of a sensor according to a first exemplary embodiment of the present invention. FIG. 1a shows the time sequence of bus data packets 100, which are transmitted over a data bus. In the first exemplary embodiment it is assumed that a single sensor delivers 24 bits (i.e., 3 bytes) of payload data per measurement, six sensors being connected to the LIN bus. The individual sensor units, which in the present first exemplary embodiment are ultrasound sensors, are represented by the reference numerals USS1 through USS6, so that a single bus data packet 100 is to be provided for each of the six sensor units USS1 through USS6. A transmission time 110 elapses until all six bus data packets 100 are transmitted according to the conventional principle.

A bus data packet 100 according to FIG. 1a is structured according to the illustration of FIG. 1b. In a first part (signaling field) which in the present exemplary embodiment has the size of 3 bytes, signaling data 120, individually predetermined for a sensor and transmitted by a master or a bus control device to the data bus, are transmitted and trigger a function in the particular addressed sensor or the particular addressed sensor unit USSx (in FIG. 1 the first sensor USS1). This triggered function may be payload data of the particular sensor unit USSx being provided after receipt of the corresponding signaling data. These payload data represent, for example, a distance of the vehicle to an object outside the vehicle measured by ultrasound or another physical variable. The payload data delivered by sensor USS1 may be inserted into a payload data field 130 adjacent to signaling field 120 and transmitted by the sensor transmitter device to the bus control device via the data bus. According to the illustration of FIG. 1b, payload data field 130 may include three payload data blocks 135 for the 3 bytes of payload data of each sensor unit USSx, each payload data block 135 having a size of 1 byte. Finally, a control data field 140 having control data is provided, in bus data packet 100, which are determined by the corresponding sensor unit USSx and represent the error recognition data (for example, CRC data), which allow a receiver to recognize a transmission error in bus data packet 100.

Standard reading of measured data (in each individual LIN message or in a bus data packet 100) of each individual sensor USS1 through USS6 (which work in the data bus as “slaves”) causes (too) much communication overhead for an optimum driver assistance function, since, for example, first a header having the signaling data and, at the end, a CRC as control data must be transmitted for each packet according to the communication standard for the corresponding data bus. This results in an unfavorable net to gross data ratio.

However, since often considerably more payload data may be transmitted in a bus data packet 100 in a payload data field 130 in conventional data bus standards than the payload data that may be provided in one measurement by a sensor USSx, the data transmission may be optimized accordingly according to the exemplary embodiments and/or exemplary methods of the present invention. For example, a data transmission using a bus data packet system 100 may be used, as illustrated in FIG. 1c. In this case, not only is a dedicated bus data packet 100 used for the payload data of each individual sensor unit USS1 through USS6, but the payload data of a plurality of (here 6) sensors may be packed into payload data field 130 of a single bus data packet 100. However, in this case, the payload data of an individual sensor are split into three consecutive bus data packets: packet 1, packet 2, and packet 3. However, in a data transmission of this type it is important that the receiver unit is aware of the assignment of the payload data in the corresponding payload data blocks 135 of the particular payload data field 130, in order to be able to assign the corresponding payload data to the particular sensor units USS1 through USS6. For this reason, an assignment formula of the payload data blocks of payload data field 130 should be established in advance. For example, such an assignment formula may be established according to the illustration of FIG. 1c in such a way that the payload data of first sensor unit USS1 are placed in the first payload data block, the payload data of second sensor unit USS2 are placed in the second payload data block of the payload data field, and the payload data of third sensor unit USS3 are placed in the third payload data block of the payload data field, etc. FIG. 1c indicates an assignment of the corresponding payload data blocks of the payload data field via the labeling of the particular sensor unit. In contrast to conventional data transmission, as illustrated in FIG. 1a, the data transmission according to the arrangement of payload data in FIG. 1c functions as data transmission of a “virtual unit” which delivers a larger amount of payload data. However, for this purpose the sensor transmitter devices of the corresponding sensor units USS1 through USS6 should be configured for inserting the payload data provided by the sensor into the particular assigned payload data block in response to predetermined signaling data 120 in the signaling field.

The data transmission according to the arrangement of payload data according to FIG. 1c allows a transmission time 150 to be achieved, which provides a time savings 160 compared to transmission time 110 according to the conventional principle. This time savings 160 results from the fact that now no longer 6, but only 3 bus data packets 100 are to be transmitted, which require correspondingly less signaling data 120 and thus result in an increase in the payload data rate.

The above-specified requirements regarding optimization of the payload data are thus achieved by connecting the sensors (or their corresponding sensor transmitter units) to form a “virtual unit” (for example, to a “virtual LIN device”). Due to its operation as a “virtual unit,” the net data rate is significantly increased, for example, from 20% to 33% (1 or 2 bytes of payload data in the case of LIN standard communication) to a LIN net data rate of 60% (1 or 2 bytes of payload data in the case of “virtual LIN device” communication) in a system of 6 sensors. In addition, the “virtual LIN device” communication reduces the number of required LIN communication blocks. The increased data throughput thus results from
a higher number of payload bytes per message (i.e., per bus data packet) and
a lower number of required LIN messages (i.e., bus data packets).

The quasi-parallel data transmission of all sensors (thanks to the “virtual device” communication) makes rapid transmission of important intermediate results during the measurement possible, which is explained in greater detail below.

The advantages of the exemplary embodiments and/or exemplary methods of the present invention illustrated here with reference to the first exemplary embodiment may be summarized as follows:
the update rate of payload data from the sensors to the analyzer unit is comparable to that of a proprietary point-to-point link of the sensors
the robustness of payload data transmission from the sensors to the analyzer unit is comparable to that of a proprietary point-to-point link of the sensors to the analyzer unit
a higher net data rate or data throughput may be achieved due to
   a higher number of payload bytes per message/data packet, (i.e., better ratio of payload data to protocol frames containing the signaling data and the control data), and
   a lower number of required LIN messages or bus data packets
there is a possibility of rapidly transmitting intermediate results, this representing an improvement with respect to conventional data transmission, in particular for sensor data that are safety-critical for the vehicles' safety
the data transmission from the sensors to the analyzer unit may take place using a cost-optimized and standardized bus system, and
a bus control unit (for example, a LIN master) sees a message fully compliant with the bus standard (i.e., for example, a fully LIN compatible communication takes place on the data bus), so that further units may also be connected to the data bus without interference occurring.

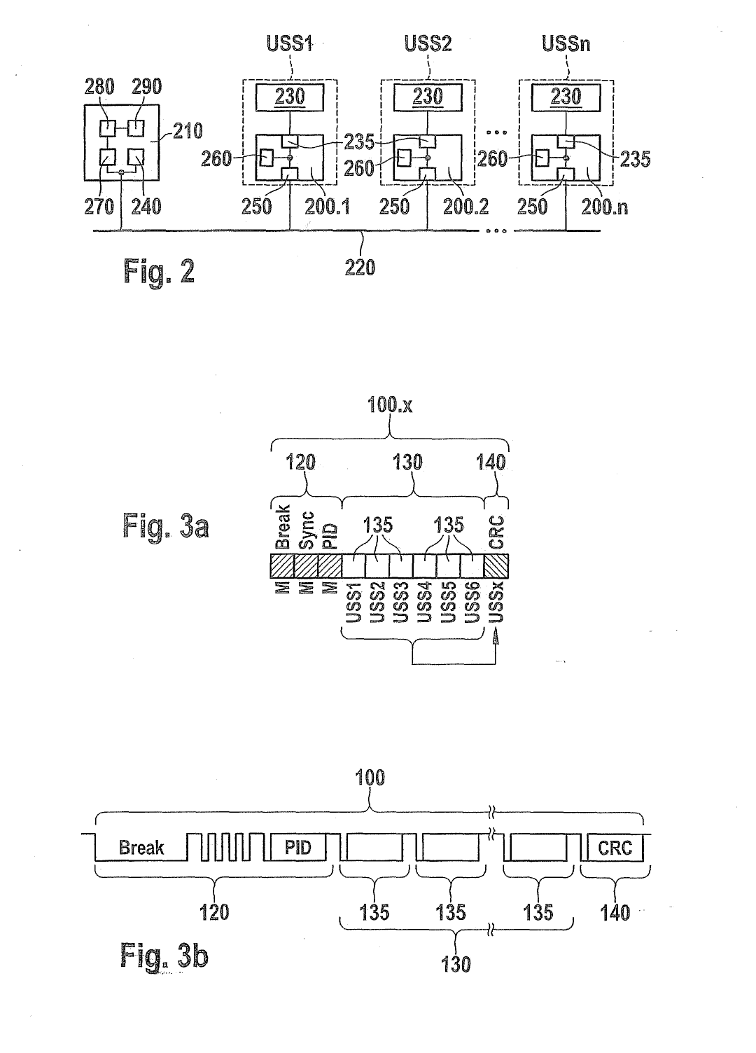

FIG. 2 shows a block diagram of a connection of exemplary embodiments of sensor transmitter devices 200.1, 200.2, . . . , 200.n to an exemplary embodiment of a bus control device 210 via a data bus 220. Sensor transmitter devices 200.1, 200.2, . . . , 200.n may each be connected to a sensor 230 to form a sensor unit USS1, USS2, . . . , USSn, sensors 230 of sensor transmitter device 200 providing data via a sensor interface 235. These data represent a physical variable. For example, the physical variable may be an ultrasound-based distance signal to an object outside the vehicle, if sensor 230 is used as a parking assistant. Bus control device 210 may be configured for controlling the data transmission via data bus 220 and for analyzing the payload data from the payload data field of a bus data packet 100.

Bus control device 210 has a transmitter unit 240, which places predetermined signaling data in the signaling field of a bus data packet 100 at a certain point in time and transmits these signaling data via data bus 220. These signaling data may be read from data bus 220 via a bus interface 250 in each sensor transmitter device 200 and interpreted. If the predetermined signaling data are recognized on data bus 220 by sensor transmitter units 200.1, 200.2, . . . , 200.n, which initializes a data transmission of payload data of sensors 230 of the different sensor units USS1, USS2, USSn, each of sensor transmitter devices 200.1, 200.2, . . . , 200.n and the particular bus interface 250 may insert one byte of payload data into payload data block 135 of the payload data field of a bus data packet 100, reserved for the corresponding sensor transmitter device 200.1, 200.2, . . . , 200.n. The position at which the payload data of the particular sensor unit USS1, USS2, USSn may be inserted into payload data field 130 is individually stored in a memory 260 for each of sensor transmitter devices 200.1, 200.2, . . . , 200.n. Bus interface 250 of each sensor transmitter device 200.1, 200.2, . . . , 200.n thus first retrieves the position information from corresponding memory 260, and inserts at least part of the payload data of the corresponding sensor 230 into payload data block 135 defined by the position information. In this way, a bus data packet 100 may be generated, which looks to bus control device 210 as if it originated from a single unit. Sensor units USS1, USS2, USSn are thus connected together as a “virtual sensor.” In bus control device 210, the payload data are analyzed in such a way that the payload data in the payload data blocks of the payload data field are read via a receiver interface 270 and are interpreted in an assignment unit 280 according to an assignment formula as belonging to the different sensor transmitter units 200.1, 200.2, . . . 200.n. The assignment formula, in which an exclusive reservation of payload data blocks of the payload data field for transmitting the payload data of the different sensor transmitter devices 200.1, 200.2, . . . , 200.n to bus control device 210 is stored, may be taken from a corresponding memory 290.

Due to the above-described exemplary embodiment of the present invention, the individual sensor units or sensor transmitter devices are connected together to form a dependent and controlled “virtual unit,” i.e., a “virtual slave” or a “virtual device,” which may be composed of up to 8 individual “slaves” (i.e., individual sensor units). In each measured data packet 100, each “slave” may fill one byte at an exactly defined location. This exactly defined location in the measured data packet (payload data field) is defined via a sensor ID, which is stored in a memory in each sensor unit, or in each sensor transmitter device 100.

A defined slave or a defined sensor transmitter device (for example, the first slave USS1 or the last slave USS6) generates, for example, CRC control data for the entire packet 100 to detect a transmission error in the payload data and to preserve the transmission format of the data bus. The number of slaves should be known for generating control data in order to enable the corresponding slave to append the CRC control data at the correct position in bus data packet 100. The master or bus control unit sees this packet 100 as a single LIN bus message having the correct CRC, as if it had been sent by a single slave, i.e., the bus control device sees an interconnection of the different sensors forming a “virtual device.”

Bus data packet 100 therefore has the format illustrated in FIG. 3a, the signaling data Break, Sync, and PID (Packet ID) being transmitted by master M or bus control device 210 in the first three bytes (signaling field 120) of bus data packet 100. The following payload data 130 are filled by the particular sensors or the corresponding sensor transmitter devices into the payload data blocks (here having the size of 1 byte) of payload data field 130 of bus data packet 100. One of sensor transmitter units USSx generates CRC control data (size: 1 byte) and fills them into control data field 140 of bus data packet 100. Bus data packet 100 is thus filled by different units which are all connected to data bus 220 in parallel. FIG. 3b shows a detailed illustration of a structure of a bus data packet 100.

The results of a sensor measurement (which generates, for example, payload data 1 to 3 bytes long) are transmitted as partial payload data by repeating the above packet 100 (with a different package ID (PID)). The individual partial results of the measurements (partial payload data), which are contained in payload data fields 130 of the following bus data packets 100, are analyzed and combined in master M or the bus control unit in an application “above” the LIN driver.

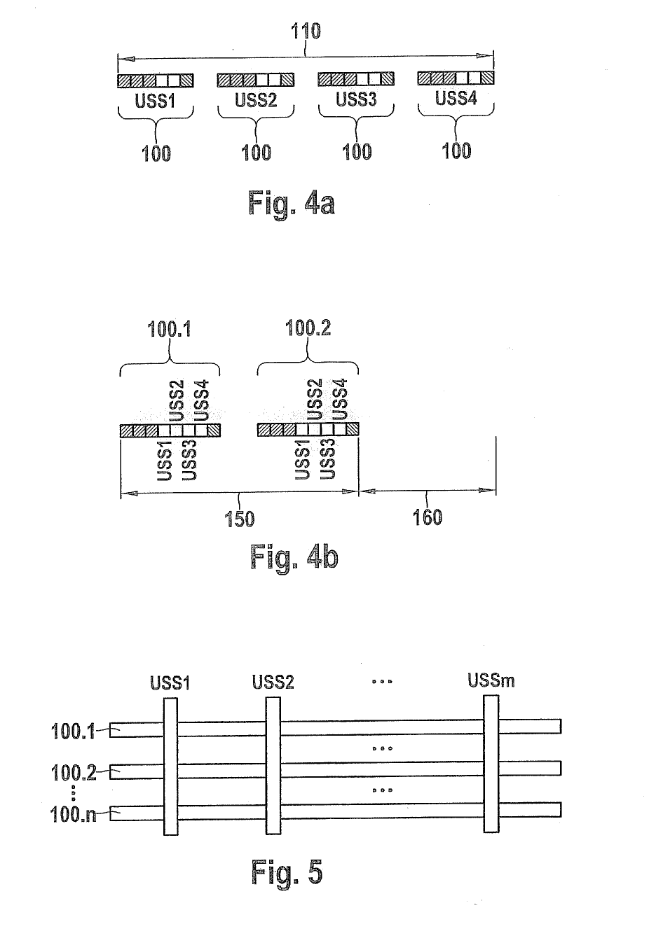

FIG. 4 shows a second exemplary embodiment of the present invention. According to this exemplary embodiment, each sensor measurement contains 13 bits of payload data (i.e., 2 bytes per sensor are needed for transmitting the payload data of this measurement), and 4 sensors or 4 sensor transmitter units should be connected to the data bus. FIG. 4a shows a structure of the data transmission if there were a conventional data transmission with one bus data packet to be provided for each sensor (4 bus data packets). However, if the principle proposed herein is used, a structure of bus data packets 100 such as illustrated in FIG. 4b results, where only 2 bus data packets need to be used. Therefore, FIGS. 4a and 4b clearly show again that a time savings 160 results due to the use of the principle proposed herein. The time savings of the “virtual device” approach proposed herein, compared to the “standard data bus” approach, amounts to approximately 30% in each of the two scenarios presented in FIGS. 1 and 4.

The principle proposed herein results in the communication matrix structure illustrated in FIG. 5 for transmitting the results of a sensor measurement (for example, an ultrasound measurement). Each sensor USS1, . . . , USSm fills at least one payload data block of a bus data packet 100.1. The remaining payload data occurring in a sensor measurement are transmitted in subsequent bus data packets 100.2 through 100.n; the payload data of a sensor in each of bus data packets 100.1, 100.2 through 100.n should be placed at a precisely specified location in the payload data field.

If there is a sufficiently large payload data field in a bus data packet, two or more payload data blocks in a bus data packet 100.y may be filled with payload data of a single sensor USSx. However, this should be known in an appropriate assignment formula in the analyzer unit, to make a correct assignment of the information contained in the particular payload data blocks to the individual sensors possible. Such a procedure could result in an even higher transmission rate and an even higher net data rate, since fewer bus data packets would be needed for transmitting the payload data of one sensor USSx to the analyzer unit.

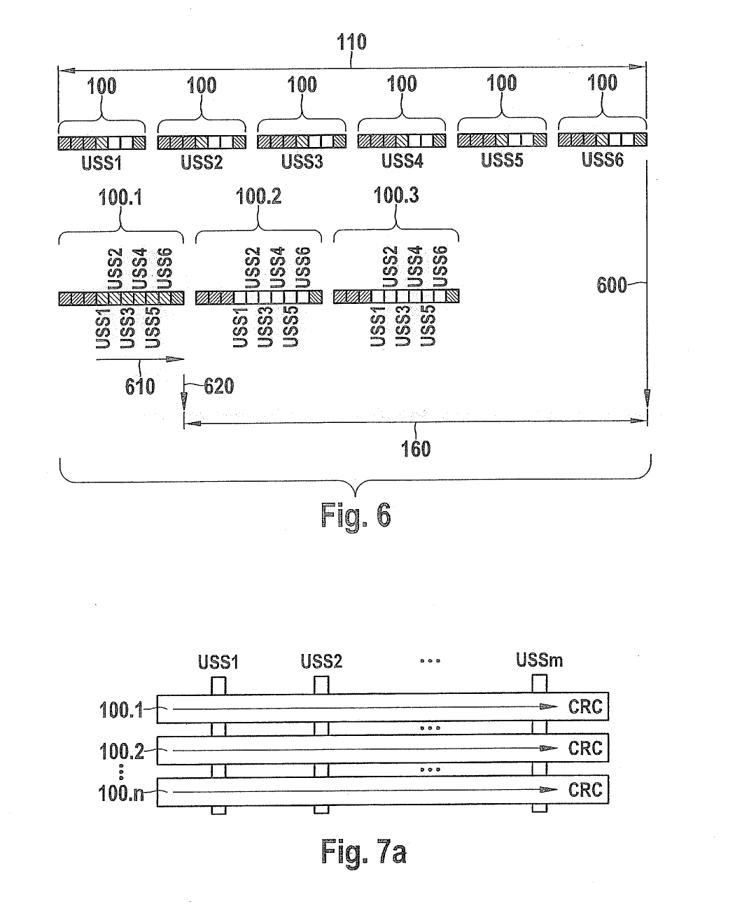

As mentioned previously, the principle presented herein also allows rapid transmission of intermediate results of a sensor measurement. Intermediate results may thus be time-compressed and transmitted in one message for all sensors USS1 through USS6. This makes the timely response of the system to relevant intermediate results/events possible. Such a rapid transmission of intermediate results is shown in FIG. 6 as an example, the important intermediate results to be transmitted as rapidly as possible being shown cross-hatched in FIG. 6. If a conventional standard data transmission is used (as schematically shown in the upper illustration of FIG. 6), no important intermediate results may be transmitted in advance. Instead, all sensor measurement data, including the important intermediate measured values for all sensors, are available only after the complete transmission time 110, since each sensor transmits the intermediate result as a part of its message (situation 600).

However, if the sensor measurement data are split into a plurality of bus data packets, the important intermediate measured values are available in the analyzer unit as early as after the transmission of the first bus data packet 100.1 (situation 610) and may therefore be rapidly processed (situation 620). For example, a safety arrangement may be appropriately activated in a timely manner (for example, automatic braking may be initiated). Due to the transmission of the important intermediate results, an even more significant time savings 160 may thus be achieved, as is apparent from the exemplary embodiments of FIGS. 1 and 4.

However, undetected corruption of data of a message/a bus data packet is possible due to the successive input of the data bytes from the individual sensors and the subsequent computation of the message CRC as control data by a dedicated slave. A payload data set of a sensor measurement (which is transmitted via bus data packets 100.1 through 100.n) may be protected by using n bits, which are inserted into or appended to the payload data to be transmitted as sensor-specific control data (for example, again as CRC having 1 to 3 bits).

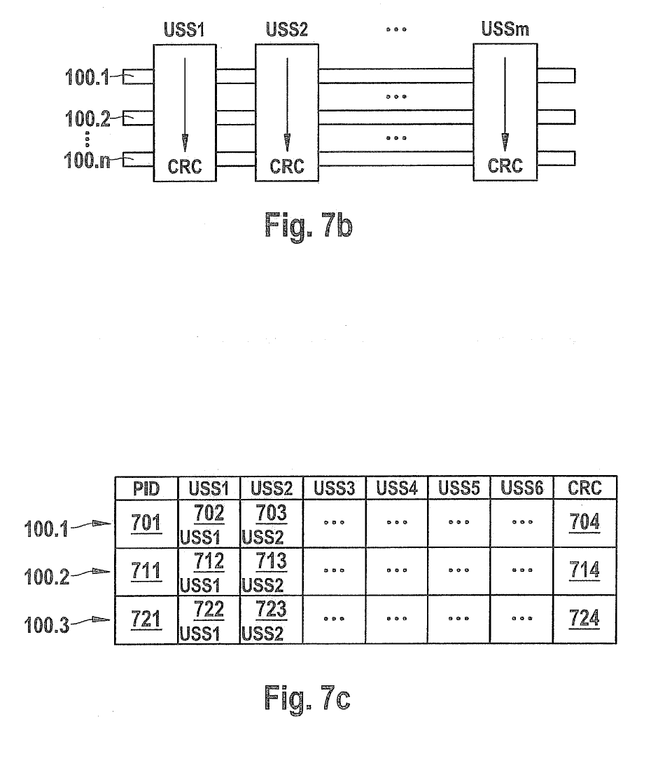

FIG. 7a shows a communication matrix structure according to a standard CRC algorithm in a data bus having a conventional bus data packet structure. For each bus data packet or for any piece of payload data in the payload data blocks of bus data packet 100.1, 100.2, . . . , 100.n, separate control data (for example, CRC data) are generated and filled into control data field 140 of the particular bus data packet 100.1, 100.2, . . . , 100.n. According to the principle additionally proposed herein, sensor control data, which allow for an erroneous transmission of the payload data of an individual sensor, may also be generated for securing the payload data of an individual sensor. FIG. 7b illustrates a communication matrix structure which would result from the use of a principle of this type. In this case, control data (for example, again, CRC data) are generated for the payload data of each individual sensor USS1, USS2, USSm, which are inserted at the end of each column, which represent the payload data of the corresponding sensors USS1, USS2, . . . USSm. In this way, each payload data set of a sensor may be provided with optional additional data security (for example, in the form of CRC) for enhancing data safety.

FIG. 7c shows, in the form of a table, the data content of the individual data blocks and of the control data field of the different bus data packets. First bus data packet 100.1 contains in signaling field PID 701 an identifier of the first measured data of the corresponding sensor units USS1 through USS6. The first part of the measured data from first sensor unit USS1 is inserted into first payload data block 702, the first part of the measured data of second sensor unit USS2 being inserted into second payload data block 703 of first bus data packet 100.1. The procedure is similar for the other payload data blocks of first bus data packet 100.1. Subsequently, control data 704 for recognizing a transmission error in the payload data of first bus data field 100.1 are inserted into control data field 140, or CRC.

Second bus data packet 100.2 contains in signaling field PID 711 an identifier of the second measured data of the corresponding sensor units USS1 through USS6. The first part of the measured data from the first sensor unit USS1 is inserted into first payload data block 702, the second part of the measured data of second sensor unit USS2 being inserted into second payload data block 713 of second bus data packet 100.2. The procedure is similar for the other payload data blocks of second bus data packet 100.2. Subsequently, control data 714 for recognizing a transmission error in the payload data of second bus data field 100.2 are inserted into control data field 140, or CRC.

Third bus data packet 100.3 contains, in signaling field PID 721, an identifier of the third measured data of the corresponding sensor units USS1 through USS6. The third part of the measured data from first sensor USS1 and certain sensor-specific control data (CRC) of first sensor unit USS1 are inserted into first payload data block 722, the third part of the measured data of second sensor unit USS2 and also certain sensor-specific control data (CRC) of second sensor unit USS2 being inserted into second payload data block 703 of third bus data packet 100.3. The procedure is similar for the other payload data blocks of third bus data packet 100.3. Finally, control data 724 for recognizing a transmission error in the payload data of third bus data field 100.3 are inserted into control data field 140, or CRC. When fewer than six sensors are used on a bus, the messages get shortened accordingly.

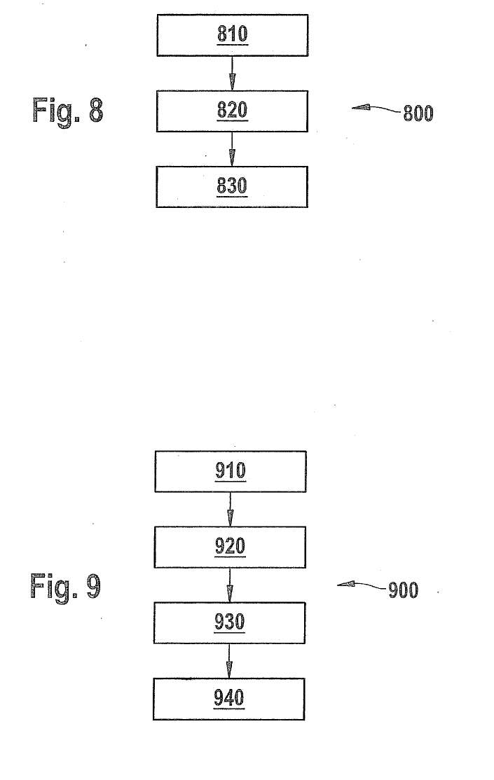

Furthermore, the exemplary embodiments and/or exemplary methods of the present invention creates a method 800 for transmitting the payload data from a sensor transmitter device to a bus control device using a data bus as illustrated in FIG. 8 as a flow chart. The data bus should be configured for simultaneous transmission of bus data packets between a plurality of sensor transmitter devices and the bus control device, the bus data packets including at least one signaling field and one payload data field having a plurality of payload data blocks. Method 800 has a first step of receiving 810 payload data of a sensor, which represent a physical quantity. Furthermore, method 800 includes a step of reading 820 position information which identifies at least one payload data block from the payload data field, which is reserved exclusively for the transmission of payload data of the sensor transmitter device to the bus control device. Finally, method 800 has a step of receiving 830 predetermined signaling data in the signaling field of a bus data packet and placing, in response thereto, at least part of the payload data received via the sensor interface in the at least one payload data block of the bus data packet specified by the position information.

The exemplary embodiments and/or exemplary methods of the present invention also creates a method 900, illustrated in FIG. 9 as a flow chart, for assigning payload data from a bus data packet to different sensor transmitter devices. The bus control device should be connectable to a data bus of a vehicle which is configured for simultaneous transmission of bus data packets between a plurality of sensor transmitter devices and the bus control device, the bus data packets including at least one signaling field and one payload data field having a plurality of payload data blocks. Method 900 has a step of placing 910 predetermined signaling data in the signaling field of a bus data packet and transmitting the predetermined signaling data to the data bus. Furthermore, method 900 has a step of retrieving 920 an assignment formula from a memory, the assignment formula representing an exclusive reservation of individual payload data blocks of the payload data field for transmitting the payload data of the corresponding sensor transmitter devices to the bus control device. Method 900 also includes a step of reading 930 payload data from the payload data blocks of the payload data field in response to the predetermined signaling data transmitted from the transmission interface; and a step of assigning 940 the read payload data to the different sensor transmitter devices according to the assignment formula.

What is claimed is:

1. A sensor transmitter device for transmitting payload data of a sensor to a bus control device and being connectable to a data bus of a vehicle, the data bus being configured for simultaneous transmission of bus data packets between a plurality of sensor transmitter devices and a bus control device, comprising:
a sensor interface to receive payload data which represent a physical quantity, wherein each of the bus data packets include at least one signaling field and one payload data field having a plurality of payload data blocks;
a memory configured for storing position information which identifies at least one payload data block from the payload data field, which is reserved exclusively for the transmission of payload data from the sensor transmitter device to the bus control device; and
a bus interface configured for placing, after receiving predetermined signaling data in the signaling field, at least part of the payload data received via the sensor interface in the payload data block specified by the position information.

2. The sensor transmitter device of claim 1, wherein the bus interface is configured so that no payload data received from the sensor interface is placed in at least one payload data block of the payload data field.

3. The sensor transmitter device of claim 1, wherein the bus data packet also includes a control data field, wherein the bus interface is configured for extracting, from those payload data blocks which are not reserved for exclusive payload data transmission for the sensor transmitter device, transmission data of at least one other sensor transmitter device and for ascertaining control data (CRC) from the extracted transmission data and from at least part of the sensor payload data received from the sensor interface, the bus interface being further configured for placing the determined control data (CRC) in the control data field of the bus data packet.

4. The sensor transmitter of claim 1, wherein the bus interface is configured to divide the payload data received from the sensor interface into a plurality of partial payload data and to transmit the different partial payload data in payload data blocks of different bus data packets to the bus control device.

5. The sensor transmitter device of claim 4, wherein the bus interface is configured for determining error recognition data (CRC) from the partial payload data and for transmitting the error recognition data in a payload data block of another bus data packet assigned to the sensor transmitter device exclusively for data transmission to the bus control device.

6. The sensor transmitter device of claim 4, wherein the bus interface is configured for transmitting partial payload data having a high priority for the driving safety of the vehicle to the bus control device earlier than partial payload data having a low priority for the driving safety of the vehicle.

7. A method for transmitting payload data from a sensor transmitter device to a bus control device using a data bus, which is configured for simultaneous transmission of bus data packets between a plurality of sensor transmitter devices and the bus control device, the method comprising:
receiving payload data of a sensor which represent a physical quantity, the bus data packets including at least one signaling field and one payload data field having a plurality of payload data blocks;
reading position information which identifies at least one payload data block from the payload data field, which is reserved exclusively for the transmission of payload data of the sensor transmitter device to the bus control device; and
receiving predetermined signaling data in the signaling field of the bus data packet, and placing, in response thereto, at least part of the received payload data in the at least one payload data block specified by the position information.

8. A bus control device for assigning payload data from a bus data packet to different sensor transmitter devices, the bus control device being connectable to a data bus of a vehicle, which is configured for simultaneous transmission of bus data packets between a plurality of sensor transmitter devices and the bus control device, the bus data packets including at least one signaling field and one payload data field having a plurality of payload data blocks, the bus control device comprising:
a transmitter unit configured to place predetermined signaling data in a signaling field of a bus data packet and to transmit the signaling data to the data bus, the bus data packets including at least one signaling field and one payload data field having a plurality of payload data blocks;
a memory to store an assignment formula of exclusive reservation of payload data blocks of the payload data field for transmitting the payload data of the different sensor transmitter devices;
a receiving interface configured to read, in response to the predetermined signaling data transmitted by the transmission interface, payload data from the payload data blocks of the payload data field; and
an assignment unit to assign the read payload data to the different sensor transmitter devices according to the assignment formula.

9. The bus control device of claim 8, wherein the assignment unit is further configured for obtaining a sequence of payload data for a single sensor transmitter device from consecutive bus data packets, and wherein the assignment unit is further configured to recognize a transmission error of the payload data for the corresponding sensor transmitter device, using a sequence of payload data.

10. The bus control device of claim 9, the payload data of a sensor having a data volume which is to be transmitted to the bus control device as partial payload data in payload data blocks of a plurality of consecutive bus data packets, wherein the bus control device is configured for activating, after receiving first partial payload data in a payload data block of a first bus data packet, another unit prior to analyzing second partial payload data, which may be received from the bus control device in a payload data block of a subsequent bus data packet.

11. The bus control device of claim 8, wherein the transmitter unit is configured for selecting the predetermined signaling data from a set of different predetermined signaling data.

12. A method for assigning payload data from a bus data packet to different sensor transmitter devices, a bus control device being connectable to a data bus of a vehicle, which is configured for simultaneous transmission of bus data packets between a plurality of sensor transmitter devices and the bus control device, the method comprising:
placing predetermined signaling data in a signaling field of a bus data packet and transmitting the predetermined signaling data to the data bus, the bus data packets including at least one signaling field and one payload data field having a plurality of payload data blocks;
retrieving an assignment formula from a memory, the assignment formula representing an exclusive reservation of individual payload data blocks of the payload data field for transmitting the payload data of the corresponding sensor transmitter devices to the bus control device;
reading the payload data from the payload data blocks of the payload data field in response to the transmitted predetermined signaling data; and
assigning the read payload data to the different sensor transmitter devices according to the assignment formula.
